(19) United States
(12) Patent Application Publication
(10) Pub. No.: US 2025/0372515 A1
(43) Pub. Date: Dec. 4, 2025

(54) SEMICONDUCTOR DEVICE

(71) Applicant: Samsung Electronics Co., Ltd., Suwon-si (KR)

(72) Inventors: Jisoo PARK, Suwon-si (KR); Jung Han LEE, Suwon-si (KR); Jaehyoung LIM, Suwon-si (KR); Byung-Sung KIM, Suwon-si (KR); Kwanyoung CHUN, Suwon-si (KR)

(73) Assignee: Samsung Electronics Co., Ltd., Suwon-si (KR)

(21) Appl. No.: 18/956,559

(22) Filed: Nov. 22, 2024

(30) Foreign Application Priority Data
Jun. 3, 2024 (KR) 10-2024-0072739

(51) Int. Cl. H01L 23/528; H01L 29/423; H01L 29/775; H01L 29/786

(52) U.S. Cl. CPC H01L 23/5283; H10D 30/43; H10D 30/6735; H10D 30/6757

(57) ABSTRACT

Some example embodiments provide a semiconductor device comprising a first lower gate structure extending in a first direction, an upper device isolation structure extending from the first lower gate structure in the first direction, a second lower gate structure spaced apart from the first lower gate structure in a second direction, the second direction intersecting the first direction, and the second lower gate structure extending in the first direction, an upper gate structure extending from the second lower gate structure in the first direction, a lower active region extending in the second direction and extending through the first lower gate structure, an upper active region extending in the second direction and extending through the upper gate structure, and a first contact plug extending through the upper device isolation structure in a third direction, and the first contact plug contacting the first lower gate structure.

### CROSS-REFERENCE TO RELATED APPLICATION

This application claims priority to Korean Patent Application No. 10-2024-0072739, filed in the Korean Intellectual Property Office on Jun. 3, 2024, the entire contents of which are hereby incorporated by reference.

### BACKGROUND

Some example embodiments relate to a semiconductor device.

A semiconductor device may be a core component used to control and/or amplify an electrical signal in an electronic device, and various types of semiconductor devices may be manufactured. For example, a memory device may be mainly used to store and retrieve data, while a non-memory device may be used to control or amplify an electrical signal. The semiconductor device may be a core component of electronic devices and plays various roles such as various important roles in various fields including computers, communication equipment, consumer electronics, etc.

With the development of various fields of industry, the performance and function expectations of electronic devices are increasing. Accordingly, higher-performance characteristics of semiconductor devices may be desired, and the integration density of semiconductor devices is increasing. Various methods for forming semiconductor devices with improved performance and/or improved integration density are being studied.

### SUMMARY

According to some example embodiments of the present disclosure, a semiconductor device may comprise a first lower gate structure extending in a first direction, an upper device isolation structure extending from the first lower gate structure in the first direction, a second lower gate structure spaced apart from the first lower gate structure in a second direction, the second direction intersecting the first direction, and the second lower gate structure extending in the first direction, an upper gate structure extending from the second lower gate structure in the first direction, a lower active region extending in the second direction and extending through the first lower gate structure, an upper active region extending in the second direction and extending through the upper gate structure, and a first contact plug extending through the upper device isolation structure in a third direction, the third direction intersecting the first direction and the second direction, and the first contact plug contacting the first lower gate structure.

According to some example embodiments of the present disclosure, a semiconductor device may comprise a first lower gate structure extending in a first direction, an upper device isolation structure extending from the first lower gate structure in the first direction, a lower device isolation structure spaced apart from the first lower gate structure in a second direction, the second direction intersecting the first direction, and lower device isolation structure extending in the first direction, an upper gate structure extending in the first direction on the lower device isolation structure, a lower active region extending in the second direction to intersect the first lower gate structure, and the lower active region including a lower channel region surrounded by the first lower gate structure, an upper active region extending in the second direction to intersect the upper gate structure, and the upper active region including an upper channel region surrounded by the upper gate structure, and a first contact plug extending through the upper device isolation structure in a third direction, the third direction intersecting the first direction and the second direction, and the first contact plug contacting the first lower gate structure, a second contact plug extending in the third direction and contacting the upper gate structure, and a connection wire connected to an upper end of each of the first contact plug and the second contact plug.

According to some example embodiments of the present disclosure, a semiconductor device may comprise a first lower gate structure extending in a first direction, an upper device isolation structure extending from the first lower gate structure in the first direction and including an insulating material, a lower device isolation structure extending in the first direction and spaced apart from the first lower gate structure in a second direction, the second direction being orthogonal to the first direction, and the lower device isolation structure being electrically shorted, an upper gate structure extending from the lower device isolation structure in the first direction, a lower active region extending in the second direction to intersect the first lower gate structure, and the lower active region including a lower channel region surrounded by the first lower gate structure, a lower source and drain region on a side surface of the first lower gate structure, an upper active region extending in the second direction to intersect the upper gate structure, and the upper active region including an upper channel region surrounded by the upper gate structure, an upper source and drain region on a side surface of the upper device isolation structure, a first contact plug extending through the upper device isolation structure in a third direction, the third direction intersecting the first direction and the second direction, and the first contact plug in contact at a lower end with the first lower gate structure, a second contact plug on the upper gate structure in the third direction and contacting a lower end of the upper gate structure, and a connection wire extending in the second direction and contacting an upper end of the first contact plug and an upper end of the second contact plug.

According to some example embodiments of the present disclosure, the electrical characteristics of the semiconductor device may be improved.

According to some example embodiments of the present disclosure, the integration density and design freedom of the semiconductor device may be improved.

### BRIEF DESCRIPTION OF THE DRAWINGS

FIG. 1 is a perspective view provided to describe some example embodiments of a semiconductor device.

FIG. 2 is a cross-sectional view taken along line A-A of FIG. 1.

FIG. 3A illustrates some example embodiments of the semiconductor device of FIG. 1 when viewed from above.

FIG. 3B illustrates other example embodiments of the semiconductor device when viewed from above.

FIG. 4 illustrates some example embodiments of the semiconductor device of FIG. 1 when viewed from below.

FIG. 5 is a cross-sectional view taken along line B-B of FIG. 1.

FIG. 6 is a cross-sectional view taken along line C-C of FIG. 1.

FIG. 7 is a diagram provided to explain some example embodiments of a semiconductor device.

FIG. 8 illustrates the semiconductor device of FIG. 7 when viewed from below.

FIG. 9 is a diagram provided to explain some example embodiments of a semiconductor device.

FIGS. 10 to 19 are diagrams provided to explain some example embodiments for methods for manufacturing a semiconductor device.

FIGS. 20 to 23 are diagrams provided to explain some example embodiments of a methods for manufacturing a semiconductor device.

### DETAILED DESCRIPTION

In the present disclosure, although the first, second, etc. are used to describe various devices or components, these devices or components are not limited by these terms. It should be understood that these terms are only used to distinguish one device or component from another device or component. It goes without saying that the first device or component mentioned below may be the second device or component within the technical idea of the present disclosure.

A semiconductor device according to some example embodiments may include a metal-oxide-semiconductor field effect transistor (MOSFET), and more specifically, a gate-all-round (GAA) transistor and a three-dimensional semiconductor device referred to as a multi-bridge channel FET (MBCFET). The three-dimensional semiconductor device may include a three-dimensional multi-stack semiconductor device designed such that semiconductor channel regions of the n-type FET (nFET) and the p-type FET (pFET) are stacked on top of each other.

Hereinafter, a semiconductor memory device and a method of manufacturing the same will be described in detail with reference to drawings.

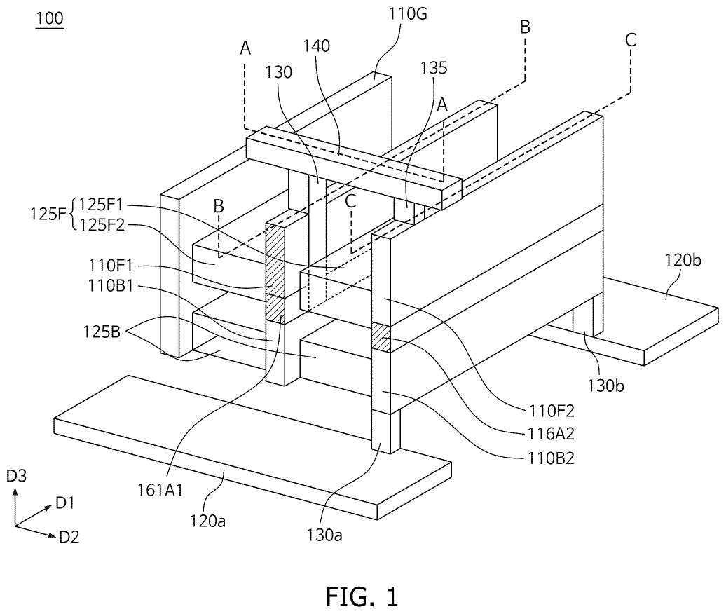

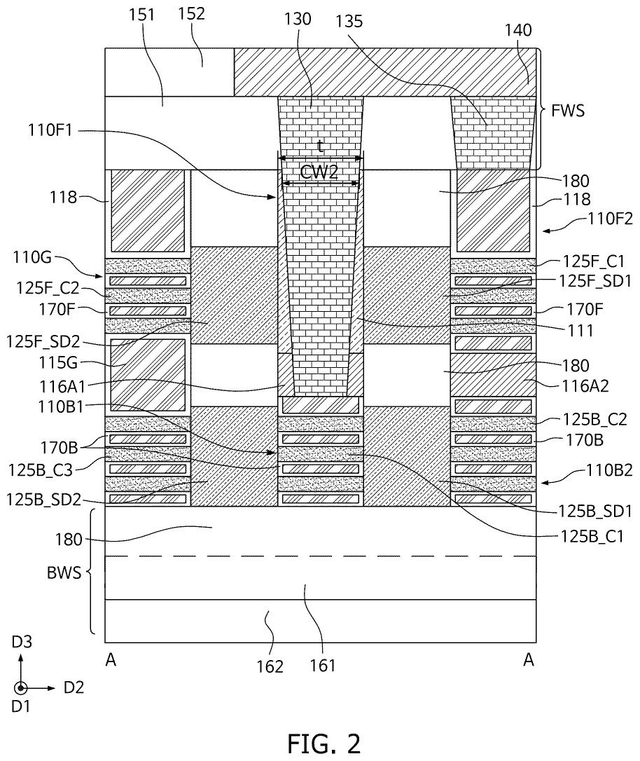

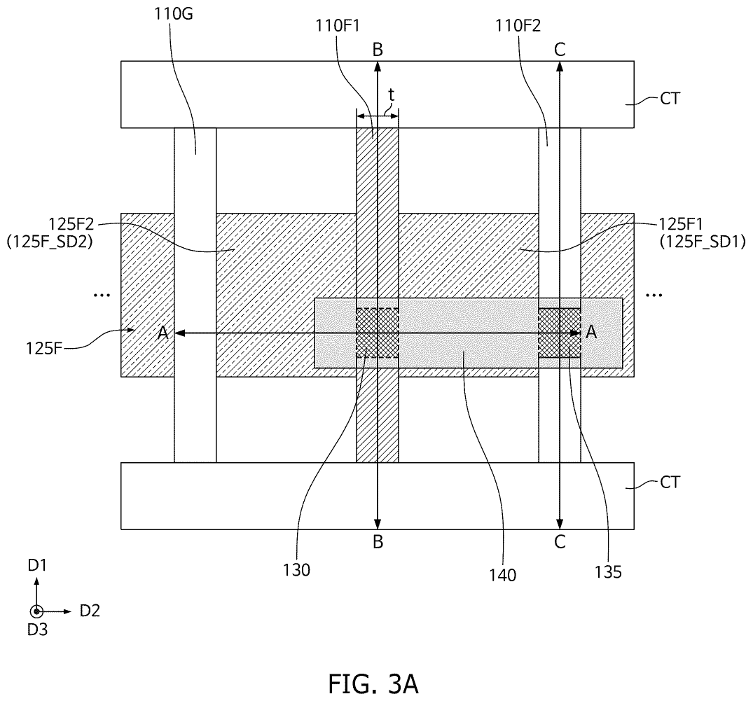

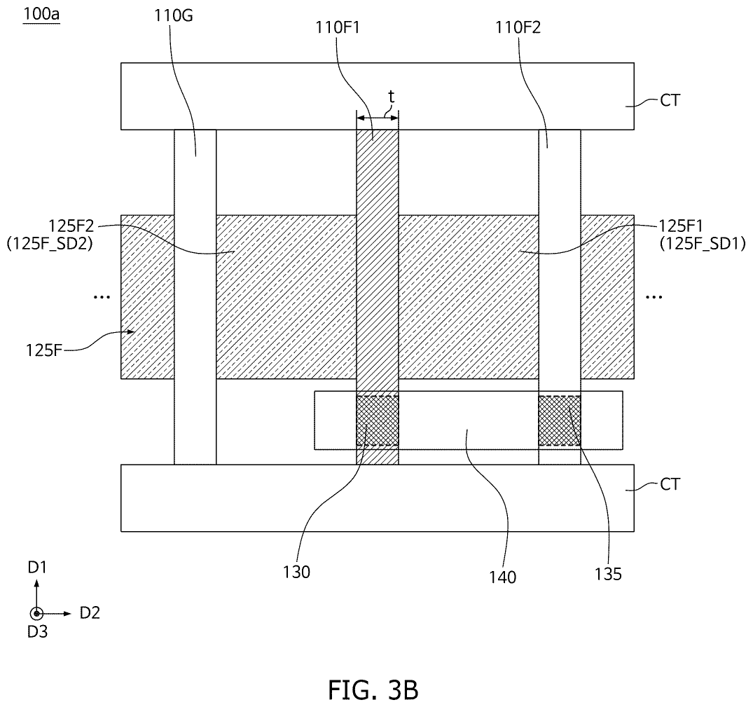

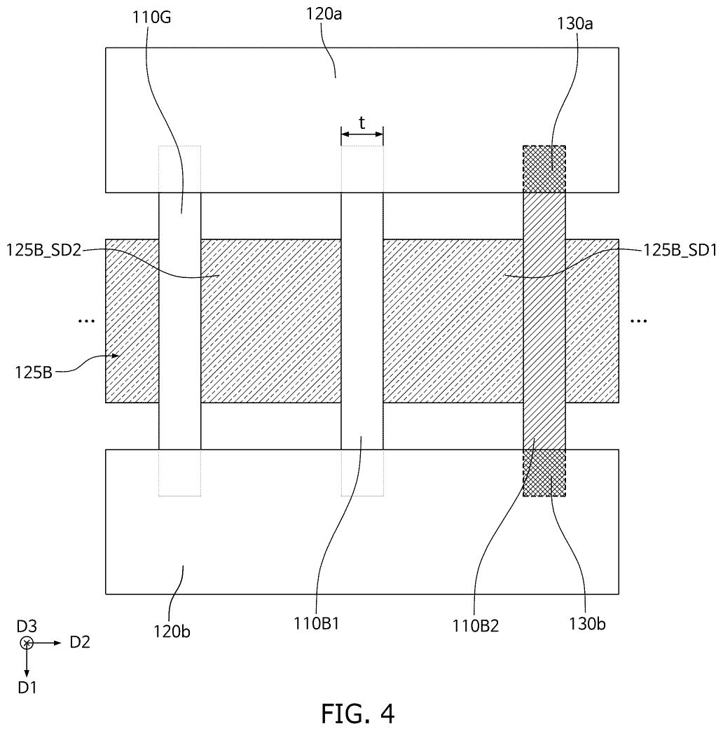

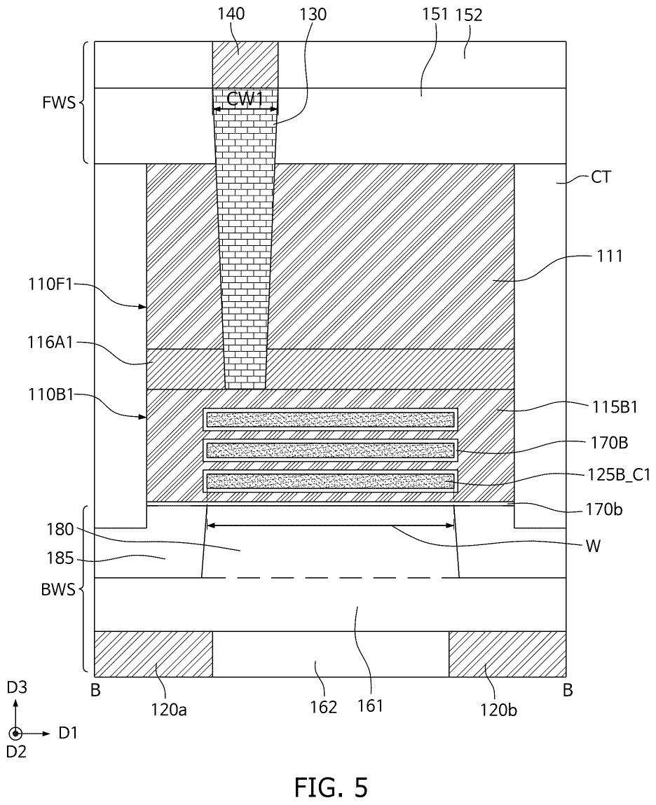

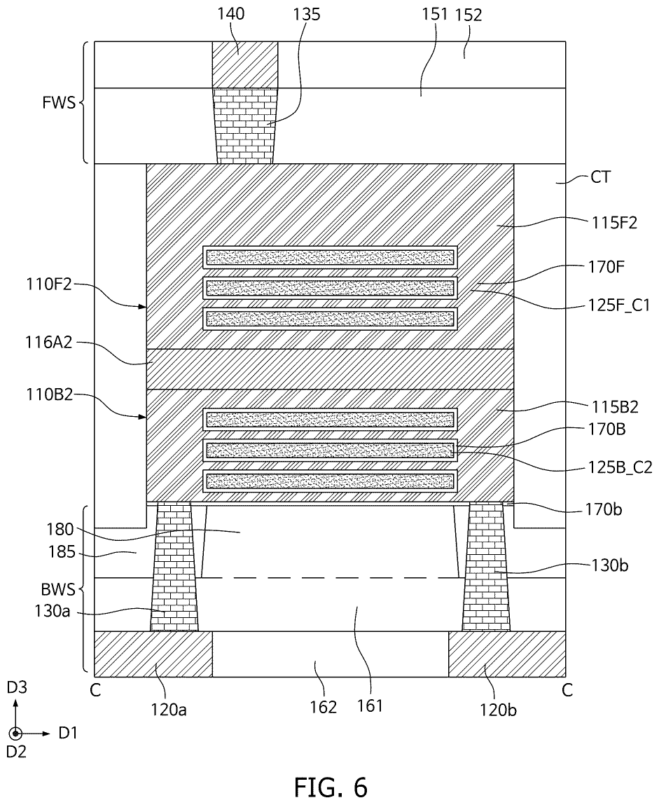

FIG. 1 is a perspective view provided to explain some example embodiments of a semiconductor device. FIG. 2 is a cross-sectional view taken along line A-A of FIG. 1. FIG. 3A illustrates the semiconductor device of FIG. 1 when viewed from above. FIG. 3B illustrates other example embodiments of the semiconductor device when viewed from above. FIG. 4 illustrates the semiconductor device of FIG. 1 when viewed from below. FIG. 5 is a cross-sectional view taken along line B-B of FIG. 1. FIG. 6 is a cross-sectional view taken along line C-C of FIG. 1.

Referring to FIGS. 1 to 6, a semiconductor device 100 may include a first lower gate structure 110B1, an upper device isolation structure 110F1, a second lower gate structure 110B2, an upper gate structure 110F2, a lower active region 125B, and an upper active region 125F, an upper wiring structure FWS, and a lower wiring structure BWS.

The semiconductor device 100 illustrated herein may be variously designed and changed according to the type of logic device applied therein, etc. For example, the semiconductor device 100 may be used in an And-Or-Inverter (AOI) standard cell. However, example embodiments are not limited thereto, and the semiconductor device 100 may be used in various logic devices that include the structure of the semiconductor device 100. For example, it may be used to construct INV, AND, OR, NAND, NOR, XOR, OAI, MUX, BUFF, adder, filler, flip-flop, latch, delay, etc.

The first lower gate structure 110B1 and the upper device isolation structure 110F1 may extend in a first direction D1. The upper device isolation structure 110F1 may be disposed on the first lower gate structure 110B1.

The second lower gate structure 110B2 and the upper gate structure 110F2 may extend in the first direction D1. The upper gate structure 110F2 may be disposed on the second lower gate structure 110B2.

Each of the second lower gate structure 110B2 and the upper gate structure 110F2 may be disposed to be spaced apart from the first lower gate structure 110B1 and the upper device isolation structure 110F1 in a second direction D2 perpendicular to the first direction D1. Each of the first lower gate structure 110B1, the upper device isolation structure 110F1, the second lower gate structure 110B2, and the upper gate structure 110F2 extending in the first direction D1 may be limited by the gate isolation region CT and be distinct from other structures in the first direction D1.

The upper device isolation structure 110F1 may be disposed above the first lower gate structure 110B1. That is, the upper device isolation structure 110F1 may be disposed above the first lower gate structure 110B1 in a third direction D3 which is a vertical direction, and the third direction D3 may be perpendicular to both the first direction D1 and the second direction D2.

The upper device isolation structure 110F1 may be a single diffusion break (SDB). The upper device isolation structure 110F1 may be replaced with a structure including an insulating material to isolate adjacent transistors. That is, the upper device isolation structure 110F1 may be a physical single diffusion break (pSDB). The upper device isolation structure 110F1 may electrically insulate adjacent transistors from each other.

The upper gate structure 110F2 may be disposed above the second lower gate structure 110B2. That is, the upper gate structure 110F2 may be disposed above the second lower gate structure 110B2 in the third direction D3 which is the vertical direction.

The second lower gate structure 110B2 may be a lower device isolation structure. For example, the second lower gate structure 110B2 may be a single diffusion break (SDB). That is, the second lower gate structure 110B2 may electrically insulate adjacent transistors from each other. In some example embodiments of the semiconductor device 100 of FIGS. 1 to 6, the second lower gate structure 110B2 may be an electrical single diffusion break (eSDB) that is electrically shorted. In another example, the second lower gate structure 110B2 may be a physical single diffusion break including an insulating material, like the first upper gate structure 110F1.

The lower wiring structure BWS may include a first power line 120a and a second power line 120b. The first power line 120a and the second power line 120b may extend in the second direction D2. The first power line 120a and the second power line 120b may be connected to the same or different power sources.

The lower wiring structure BWS may include a first lower gate contact 130a and a second lower gate contact 130b. The first lower gate contact 130a may electrically connect the first power line 120a and the second lower gate structure 110B2. An upper end of the first lower gate contact 130a may be in contact with the second lower gate structure 110B2, and a lower end of the first lower gate contact 130a may be connected to the first power line 120a.

The second lower gate contact 130b may electrically connect the second power line 120b and the second lower gate structure 110B2. An upper end of the second lower gate contact 130b may be in contact with the second lower gate structure 110B2, and a lower end of the second lower gate contact 130b may be in contact with the second power line 120b.

If the first lower gate contact 130a and the second lower gate contact 130b are connected to or grounded to the same power source through the first power line 120a and the second power line 120b, respectively, an electrical short may occur in the second lower gate structure 110B2. That is, the second lower gate structure 110B2 may be an electrical single diffusion break (eSDB) that may serve as the lower device isolation structure to limit electron movement to a second lower channel region 125B_C2.

An interlayer insulating film 180 may be disposed under the lower active region 125B2. The interlayer insulating film 180 may extend along the second direction D2. The interlayer insulating film 180 may be a region in which a lower pattern is etched and filled with an insulating material.

A field insulating film 185 may be disposed at one side of the interlayer insulating film 180. The field insulating film 185 may extend along the second direction D2. For example, the field insulating film 105 may include an oxide, a nitride, a nitride oxide, or a combination thereof. However, example embodiments are not limited thereto. Although it is illustrated that the field insulating film 105 is a single film, it is only for convenience of description, and example embodiments are not limited thereto. For example, the field insulating film 185 may be formed of a plurality of films. Meanwhile, the interlayer insulating film 180 and the field insulating film 185 may be formed of the same material, and in this case, the two insulating films may not be clearly distinct from each other.

A first lower wiring insulating film 161 and a second lower wiring insulating film 162 may be disposed under the interlayer insulating film 180. Specifically, the first lower wiring insulating film 161 may be disposed under the interlayer insulating film 180, and the second lower wiring insulating film 162 may be disposed under the first lower wiring insulating film 161.

Each of the interlayer insulating film 180, the first lower wiring insulating film 161, and the second lower wiring insulating film 162 may include at least one of silicon oxide, silicon nitride, silicon oxynitride, and a low-k material. However, example embodiments are not limited thereto.

Each of the first lower gate contact 130a and the second lower gate contact 130b may be disposed in the first lower wiring insulating film 161 and the field insulating film 185 (and/or the interlayer insulating film 180). That is, each of the first lower gate contact 130a and the second lower gate contact 130b may extend through the first lower wiring insulating film 161 and the field insulating film 185 (and/or the interlayer insulating film 180). The first power line 120a and the second power line 120b may be disposed in the second lower wiring insulating film 162.

An insulating layer 116A2 may be disposed between the upper gate structure 110F2 and the second lower gate structure 110B2. The insulating layer 116A2 may electrically insulate the upper gate structure 110F2 and the second lower gate structure 110B2.

An insulating layer 116A1 (see FIG. 2) may be disposed between the first lower gate structure 110B1 and the upper device isolation structure 110F1. The insulating layer may be formed of the same material as the insulating material filling the upper device isolation structure 110F1.

The semiconductor device 100 may include a sub gate structure 110G. The sub gate structure 110G may be spaced apart from the first lower gate structure 110B1 and the upper device isolation structure 110F1 in a direction opposite to the second direction D2. For example, as illustrated in FIG. 1, the sub gate structure 110G may be disposed opposite to the upper gate structure 110F2 and the second lower gate structure 110B2 based on the first lower gate structure 110B1 and the upper device isolation structure 110F1, but example embodiments are not limited thereto. A distance between the gate structures may be 1 Contacted-Poly-Pitch (1-CPP).

The lower active region 125B may be disposed on the lower wiring structure BWS. The lower active region 125B may extend in the second direction D2 and extend through the first lower gate structure 110B1. The lower active region 125B may extend in the second direction D2 and extend through the second lower gate structure 110B2. The lower active region 125B may include lower channel regions 125B_C1, 125B_C2, and 125B_C3 and lower source and drain regions 125B_SD1 and 125B_SD2. The upper active region 125F may be disposed on the lower active region 125B. The upper active region 125F may extend in the second direction D2 and extend through the upper gate structure 110F2. The upper active region 125F may include upper channel regions 125F_C1 and 125F_C2 and upper source and drain regions 125F_SD1 and 125F_SD2.

The upper active region 125F and the lower active region 125B may be disposed to be spaced apart from each other in the third direction D3 (i.e., a vertical direction) perpendicular to the first direction D1 and the second direction D2. The interlayer insulating film 180 may be disposed between the upper active region 125F and the lower active region 125B.

The upper active region 125F may include a first upper active region 125F1 and a second upper active region 125F2. The first upper active region 125F1 and the second upper active region 125F2 may be physically separated and electrically insulated by the upper device isolation structure 110F1. That is, the upper device isolation structure 110F1 may be positioned between the first upper active region 125F1 and the second upper active region 125F2.

The first upper active region 125F1 may intersect the upper gate structure 110F2. The second upper active region 125F2 may intersect the sub gate structure 110G. That is, the first upper active region 125F1 may extend through the upper gate structure 110F2, and the second upper active region 125F2 may extend through the sub gate structure 110G. Meanwhile, the first upper active region 125F1 may not extend through the upper device isolation structure 110F1.

The lower active region 125B may intersect both the first and second lower gate structures 110B1 and 110B2. That is, the lower active region 125B may extend through the first lower gate structure 110B1 and the second lower gate structure 110B2. The lower active region 125B may also intersect the sub gate structure 110G. Meanwhile, as another example, the lower active region 125B may not extend through the second lower gate structure 110B2. The upper active region 125F may include the upper channel regions 125F_C1 and 125F_C2. Specifically, the upper channel regions 125F_C1 and 125F_C2 may include a first upper channel region 125F_C1 surrounded by the upper gate structure 110F2, and a second upper channel region 125F_C2 surrounded by the sub gate structure 110G.

The lower active region 125B may include the lower channel regions 125B_C1, 125B_C2, and 125B_C3. Specifically, the lower channel regions 125B_C1, 125B_C2, and 125B_C3 may include a first lower channel region 125B_C1 surrounded by the first lower gate structure 110B1, the second lower channel region 125B_C2 surrounded by the second lower gate structure 110B2, and a third lower channel region 125B_C3 surrounded by the sub gate structure 110G.

Each of the first and second upper channel regions 125F_C1 and 125F_C2 and the first to third lower channel regions 125B_C1, 125B_C2, and 125B_C3 may include a plurality of sheet patterns. For example, each of the first and second upper channel regions 125F_C1 and 125F_C2 and the first to third lower channel regions 125B_C1, 125B_C2, and 125B_C3 may include three sheet patterns. However, example embodiments are not limited to the above. Unlike illustrated in FIG. 5 and FIG. 6, each of the first and second upper channel regions 125F_C1 and 125F_C2 and the first to third lower channel regions 125B_C1, 125B_C2, and 125B_C3 may include one, two, or four or more sheet patterns.

In some example embodiments, the number of sheet patterns in the first and second upper channel regions 125F_C1 and 125F_C2 may be different from the number of sheet patterns in the first to third lower channel regions 125B_C1, 125B_C2, and 125B_C3. For example, the number of sheet patterns in the first and second upper channel regions 125F_C1 and 125F_C2 may be two, and the number of sheet patterns in the first to third lower channel regions 125B_C1, 125B_C2, and 125B_C3 may be three.

Each of the first and second upper channel regions 125F_C1 and 125F_C2 and the first to third lower channel regions 125B_C1, 125B_C2, and 125B_C3 may include one of an element semiconductor material such as silicon (Si) or silicon germanium (SiGe), a group IV-IV compound semiconductor, or a group III-V compound semiconductor. However, example embodiments are not limited thereto.

For example, the group IV-IV compound semiconductor may be a binary compound or a ternary compound including at least two or more of carbon (C), silicon (Si), germanium (Ge), tin (Sn), or a compound doped with a group IV element. However, example embodiments are not limited thereto.

For example, the group III-V compound semiconductor may be one of a binary compound, a ternary compound, or a quaternary compound formed by a combination of at least one of aluminum (Al), gallium (Ga), and indium (In) as a group III element and one of phosphorus (P), arsenic (As), and antimony (Sb) as a group V element. However, example embodiments are not limited thereto.

The upper device isolation structure 110F1 may not intersect the upper active region 125F, because it 110F1 physically divides the upper active region 125F into the first upper active region 125F1 and the second upper active region 125F2. That is, the upper device isolation structure 110F1 may be the result of removing the gate electrode, the channel region, etc. and filling with an insulating material. Accordingly, the upper active region 125F may not include a channel region surrounded by the upper device isolation structure 110F1.

Referring to FIGS. 5 and 6, the first lower gate structure 110B1 may include a first lower gate electrode 115B1. The first lower gate electrode 115B1 may surround the first lower channel region 125B_C1. For example, the first lower gate electrode 115B1 may surround the sheet patterns of the first lower channel region 125B_C1.

The upper gate structure 110F2 may include an upper gate electrode 115F2. The upper gate electrode 115F2 may surround the upper channel regions 125F_C1 and 125F_C2. For example, the second upper gate electrode 115F2 may surround the sheet patterns of the first upper channel region 125F_C1.

The second lower gate structure 110B2 may include a second lower gate electrode 115B2. The second lower gate electrode 115B2 may surround the second lower channel region 125B_C2. For example, the second lower gate electrode 115B2 may surround the sheet patterns of the second lower channel region 125B_C2.

The sub gate structure 110G may intersect the lower active region 125B and the second upper active region 125F2. The sub gate structure 110G may extend in the first direction D1. The sub gate structure 110G may include a sub gate electrode 115G. The sub gate electrode 115G may surround the sheet patterns of the second upper channel region 125F_C2 and the third lower channel region 125B_C3. Electrodes surrounding the second upper channel region 125F_C2 and the third lower channel region 125B_C3 may be connected to each other in the sub gate electrode 115G. The sub gate electrode 115G may be a common gate electrode in which the electrode on the second upper channel region 125F_C2 and the electrode on the third lower channel region 125B_C3 are connected to each other.

Each of the first lower gate electrode 115B1, the upper gate electrode 115F2, the second lower gate electrode 115B2, and a sub gate electrode 115G may include at least one of a metal, a metal alloy, a conductive metal nitride, a metal silicide, a doped semiconductor material, a conductive metal oxide, and a conductive metal oxynitride. For example, each of the first lower gate electrode 115B1, the upper gate electrode 115F2, the second lower gate electrode 115B2, and the sub gate electrode 115G may include at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and a combination thereof, but example embodiments are not limited thereto.

A gate spacer 118 (see FIG. 2) may be disposed on a side surface of the second upper gate electrode 115F2 and a side surface of the gate electrode of the sub gate electrode 115G disposed on the upper side. For example, the gate spacer 118 may include at least one of silicon nitride (SiN), silicon nitride oxide (SiON), silicon oxide (SiO₂), silicon carbonate (SiOCN), silicon boron nitride (SiBN), silicon boron oxide (SiOBN), silicon oxycarbide (SiOC), and a combination thereof. However, example embodiments are not limited thereto. Although it is illustrated that the gate spacer 118 is a single film, it is only for convenience of description, and example embodiments are not limited thereto.

Although it is illustrated that each of the first lower gate electrode 115B1, the upper gate electrode 115F2, the second lower gate electrode 115B2, and the sub gate electrode 115G is a single layer, example embodiments are not limited thereto. For example, each of the first lower gate electrode 115B1, the upper gate electrode 115F2, the second lower gate electrode 115B2, and the sub gate electrode 115G may include a work function control film for adjusting a work function, and a filling conductive film for filling a space formed by the work function control film. For example, the work function control film may include at least one of TiN, TaN, TiC, TaC, TiAlC, and a combination thereof. For example, the filling conductive layer may include W or Al. However, example embodiments are not limited thereto.

The semiconductor device 100 may include structures disposed at different gate lines and heights, such as the first lower gate structure 110B1 and the upper gate structure 110F2. The first lower gate structure 110B1 and the upper gate structure 110F2 may be disposed at different positions in the second direction D2 and the third direction D3. In other words, the first lower gate structure 110B1 and the upper gate structure 110F2 may be staggered from each other.

The upper wiring structure FWS may include a connection wire 140 for transmitting a signal to the first lower gate structure 110B1 and the upper gate structure 110F2. The connection wire 140 may electrically connect the first lower gate structure 110B1 and the upper gate structure 110F2. The first lower gate structure 110B1 and the upper gate structure 110F2 may be connected to a signal source through the connection wire 140.

The upper wiring structure FWS may include a first contact plug 130 to be electrically connected to the connection wire 140. The first contact plug 130 may be disposed to extend through the upper device isolation structure 110F1. The first contact plug 130 may extend in the third direction D3. An upper end of the first contact plug 130 may be in contact with the connection wire 140. A lower end of the first contact plug 130 may be in contact with the first lower gate structure 110B1. Specifically, the first contact plug 130 may be in contact with the first lower gate electrode 115B1 so as to transfer an electrical signal to the first lower gate structure 110B1.

Referring to FIGS. 2 and 5, the first contact plug 130 may be formed such that a cross-sectional width thereof decreases from the upper end to the lower end. The first contact plug 130 may be formed such that widths CW1 and CW2 in the first and second directions D1 and D2 decrease from the upper end to the lower end.

The upper wiring structure FWS may include a second contact plug 135 disposed on the upper gate structure 110F2. The second contact plug 135 may extend in the third direction D3. An upper end of the second contact plug 135 may be in contact with the connection wire 140. A lower end of the second contact plug 135 may be in contact with the upper gate structure 110F2. The second contact plug 135 may be formed such that a cross-sectional width thereof decreases from the upper end to the lower end.

The first contact plug 130 and the second contact plug 135 may be disposed to be spaced apart from each other in the second direction D2. That is, the first contact plug 130 and the second contact plug 135 may be disposed on the same line along the second direction D2. Since the upper end of the first contact plug 130 is disposed on the upper device isolation structure 110F1 and the upper end of the second contact plug 135 is disposed on the upper gate structure 110F2, the plugs may be positioned at the same height with respect to the third direction D3. The connection wire 140 connecting the first contact plug 130 and the second contact plug 135 may extend in the second direction D2.

The upper wiring structure FWS may include a first upper wiring insulating film 151 and a second upper wiring insulating film 152. For example, each of the first upper wiring insulating film 151 and the second upper wiring insulating film 152 may include at least one of silicon oxide, silicon nitride, silicon oxynitride, and a low-k material. However, example embodiments are not limited thereto. The first contact plug 130 and the second contact plug 135 may be disposed in the first upper wiring insulating film 151. The connection wire 140 may be disposed in the second upper wiring insulating film 152.

Referring to FIGS. 1, 3, 5, and 6, regarding the signal transmission distance connecting the first lower gate structure 110B1 and the upper gate structure 110F2, the first contact plug 130 and the second contact plug 135 may extend vertically from the connection wire 140 to the first lower gate structure 110B1, and extend vertically from the connection wire 140 to the upper gate structure 110F2, respectively. That is, the first contact plug 130 and the second contact plug 135 may be connected in the shortest distance from the connection wire 140 to the first lower gate structure 110B1 and the upper gate structure 110F2, respectively. Therefore, the electrical performance of the semiconductor device 100 can be improved by shortening the wiring length.

In addition, the first lower gate structure 110B1 and the upper gate structure 110F2 may be electrically connected to each other without an additional connection structure other than the connection wire 140. For example, since the first lower gate structure 110B1 and the upper gate structure 110F2 can be electrically connected with only the connection wire 140 extending in the second direction D2, a separate wiring extending in the first direction D1 or the third direction D3 may not be required. As a result, it is possible not only to reduce the amount of metal material required for wiring and simplify the manufacturing process, but also to ensure a block area on the upper side of the semiconductor device 100.

Referring to FIG. 3B, a semiconductor device 100a according to other example embodiments may include the first contact plug 130, the second contact plug 135, and the connection wire 140 disposed so as not to overlap each other in the third direction D3. The lower end of the first contact plug 130 may not overlap the first upper active region 125F1 and the second upper active region 125F2 in the second direction D2. That is, the first contact plug 130 may be disposed outside the first upper active region 125F1 and the second upper active region 125F2 in the first direction D1.

The first contact plug 130 and the second contact plug 135 may be positioned on the same line in the second direction D2. The first contact plug 130 and the second contact plug 135 may be electrically connected to the connection wire 140. The connection wire 140 may extend in the second direction D2.

The first contact plug 130 and the second contact plug 135 may vertically extend from the connection wire 140 to the first lower gate structure 110B1, and vertically extend from the connection wire 140 to the upper gate structure 110F2, respectively. The electrical performance of the semiconductor device 100a can be improved by shortening the wiring length.

Referring to FIG. 5, the first contact plug 130 may overlap the first lower channel region 125B_C1 with respect to the third direction D3. That is, the first contact plug 130 may be disposed above the first lower channel region 125B_C1. In other words, the first contact plug 130 may be disposed above the first lower gate structure 110B1, and positioned within the width W in the first direction D1 of the first lower channel region 125B_C1.

Referring to FIGS. 2 and 3, at least a portion of the first contact plug 130 may overlap the upper active region 125F in the second direction D2. The at least portion of the first contact plug 130 may be positioned between the first upper source and drain region 125F_SD1 and the second upper source and drain region 125F_SD2. Since the lower end of the first contact plug 130 is in contact with the upper side of the first lower gate structure 110B1, and the cross-sectional width of the first contact plug 130 decreases from the upper end to the lower end, the first contact plug 130 may be positioned within the thickness t in the second direction D2 of the first lower gate structure 110B1. That is, the width CW2 of the first contact plug 130 in the second direction D2 may be less than or equal to the thickness t of the upper device isolation structure 110F1 in the second direction D2. Since the first contact plug 130 is positioned within the thickness t in the second direction D2 of the first lower gate structure 110B1, the first contact plug 130 may not be in contact with the first and second upper source and drain regions 125F_SD1 and 125F_SD2. As described above, since the upper source and drain regions 125F_SD1 and 125F_SD2 may be disposed without interference with the first contact plug 130, the width W in the first direction D1 of the upper source and drain regions 125F_SD1 and 125F_SD2 may be ensured. As a result, the effective resistance of the upper active region 125F may be decreased.

Specifically, a contact insulating film 111 may be disposed between the first contact plug 130 and the first or second upper source and drain regions 125F_SD1 and 125F_SD2 to reduce or prevent electrical conduction between the first contact plug 130 and the upper active region 125F. The contact insulating film 111 may be formed of an insulating material included in the upper device isolation structure 110F1.

A lower gate insulating film 170B may be disposed on portions of the first lower gate electrode 115B1, the second lower gate electrode 115B2, and the sub gate electrode 115G. The description of the lower gate insulating film 170B disposed on the first lower gate electrode 115B1 may be similar to the description of the lower gate insulating film 170B disposed on the second lower gate electrode 115B2. The lower gate insulating film 170B will be described mainly with respect to the first lower gate electrode 115B1.

The lower gate insulating film 170B may be disposed between the first lower gate electrode 115B1 and the first lower channel region 125B_C1 and between the first lower gate electrode 115B1 and the adjacent first lower source and drain region 125B_SD1 and second lower source and drain region 125B_SD2, respectively. Although it is illustrated that the lower gate insulating film 170B is a single film, example embodiments are not limited thereto. Unlike the illustration, the lower gate insulating film 170B may include a plurality of films.

An upper gate insulating film 170F may be disposed on portions of the upper gate electrode 115F2 and the sub gate electrode 170G. The description of the upper gate insulating film 170F disposed on the upper gate electrode 115F2 may be similar to the description of the upper gate insulating film 170F disposed on the sub gate electrode. Hereinafter, the upper gate insulating film 170F will be described mainly with respect to the upper gate electrode 115F2.

The upper gate insulating film 170F may be disposed between the upper gate electrode 115F2 and the second upper channel region 125F_C2 and between the upper gate electrode 115F2 and the adjacent first upper source and drain region 125F_SD1. Although it is illustrated that the upper gate insulating film 170F is a single film, example embodiments are not limited thereto. Unlike the illustration, the upper gate insulating film 170F may include a plurality of films.

For example, each of the lower gate insulating film 170B and the upper gate insulating film 170F may include a high-k material having a dielectric constant greater than that of silicon oxide, silicon oxynitride, silicon nitride, or silicon oxide. For example, the high-k material may include one or more of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate. However, example embodiments are not limited thereto.

The first upper source and drain region 125F_SD1 may form the second upper active region 125F2. The first upper source and drain region 125F_SD1 may be disposed at one side of the first upper channel region 125F_C1. Specifically, the first upper source and drain region 125F_SD1 may be disposed between the first upper channel region 125F_C1 and the first upper gate structure 110F1.

The second upper source and drain region 125F_SD2 may form the second upper active region 125F2. The second upper source and drain region 125F_SD2 may be disposed at one side of the second upper channel region 125F_C2. Specifically, the second upper source and drain region 125F_SD2 may be disposed between the second upper channel region 125F_C2 and the upper device isolation structure 110F1.

The first lower source and drain region 125B_SD1 may form the lower active region 125B. The first lower source and drain region 125B_SD1 may be disposed between the first lower channel region 125B_C1 and the second lower channel region 125B_C2.

The second lower source and drain region 125B_SD2 may form the lower active region 125B. The second lower source and drain region 125B_SD2 may be disposed between the second lower channel region 125B_C2 and the third lower channel region 125B_C3.

The interlayer insulating film 180 may be disposed above and below the lower source and drain regions 125B_SD1 and 125B_SD2 or the upper source and drain regions 125F_SD1 and 125F_SD2. Specifically, the interlayer insulating film 180 may be disposed under the lower source and drain regions 125B_SD1 and 125B_SD2, between the lower source and drain regions 125B_SD1 and 125B_SD2 and the upper source and drain regions 125F_SD1 and 125F_SD2, and above the upper source and drain regions 125F_SD1 and 125F_SD2. For example, the interlayer insulating film 180 may include at least one of silicon oxide (SiO), silicon nitride (SiN), silicon oxynitride (SiON), and a low dielectric constant material. For example, the low-k material may include fluorinated tetraethylorthosilicate (FTEOS), hydrogen silsesquioxane (HSQ), bis-benzocyclobutene (BCB), tetramethylorthosilicate (TMOS), octamethyleyclotetrasiloxane e (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), tonen silazen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, mesoporous silica, or a combination thereof, but is not limited thereto. However, example embodiments are not limited thereto.

Each of the first and second upper source and drain regions 125F_SD1 and 125F_SD2 and the first and second lower source and drain regions 125B_SD1 and 125B_SD2 may include an epitaxial pattern, and may be formed of a plurality of films instead of a single film. Each of the first and second upper source and drain regions 125F_SD1 and 125F_SD2 and the first and second lower source and drain regions 125B_SD1 and 125B_SD2 may include a semiconductor material. For example, each of the first and second upper source and drain regions 125F_SD1 and 125F_SD2 and the first and second lower source and drain regions 125B_SD1 and 125B_SD2 may include an element semiconductor material such as silicon (Si) or germanium (Ge). However, example embodiments are not limited thereto. In addition, for example, each of the first and second upper source and drain regions 125F_SD1 and 125F_SD2 and the first and second lower source and drain regions 125B_SD1 and 125B_SD2 may include a binary compound or a ternary compound including at least two or more of carbon (C), silicon (Si), germanium (Ge), tin (Sn), or a compound doped with a group IV element. However, example embodiments are not limited thereto. For example, each of the first and second upper source and drain regions 125F_SD1 and 125F_SD2 and the first and second lower source and drain regions 125B_SD1 and 125B_SD2 may include silicon (Si), silicon-germanium (SiGe), germanium (Ge), silicon carbide (SiC), etc., but example embodiments are not limited thereto.

The first and second upper source and drain regions 125F_SD1 and 125F_SD2 and the first and second lower source and drain regions 125B_SD1 and 125B_SD2 may have different conductivity types or the same conductivity types. That is, transistors including each of the first and second upper source and drain regions 125F_SD1 and 125F_SD2 and the first and second lower source and drain regions 125B_SD1 and 125B_SD2 may be NMOS or PMOS.

Hereinafter, a semiconductor device according to other example embodiments will be described. The same or similar configurations will be given the same reference numerals, and detailed description thereof may be omitted.

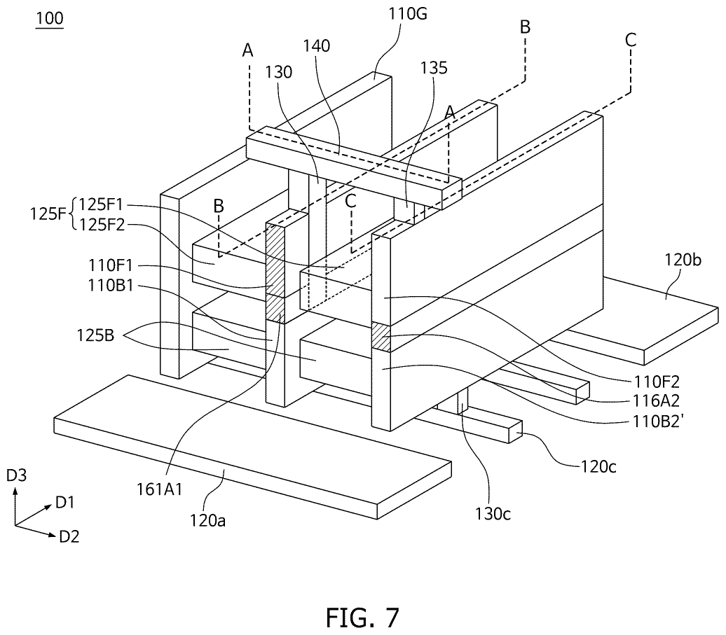

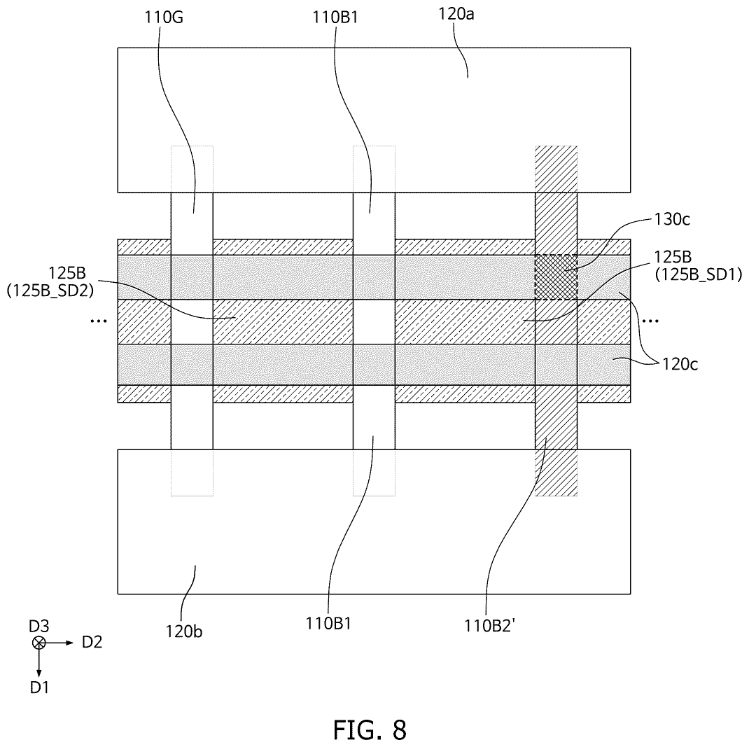

FIG. 7 is a diagram provided to explain some examples of a semiconductor device. FIG. 8 illustrates the semiconductor device of FIG. 7 when viewed from below.

Referring to FIGS. 7 and 8, a semiconductor device 100′ may include the first lower gate structure 110B1, the upper device isolation structure 110F1, the second lower gate structure 110B2, the upper gate structure 110F2, the lower active region 125B and the second upper active region 125F2, the upper wiring structure FWS, and the lower wiring structure BWS. Compared to the semiconductor device according to FIGS. 1 to 6, the semiconductor device according to FIGS. 7 and 8 differs only in the characteristics related to the lower wiring structure BWS and the second lower gate structure 110B2, and accordingly, descriptions overlapping those already described above will be omitted.

The lower wiring structure BWS may include a signal line 120c. The signal line 120c may extend along the second direction D2. One or more signal lines 120c may be arranged. If there are a plurality of signal lines 120c, each signal line 120c may be disposed to be spaced apart from each other in the first direction D1. The signal line 120c may be disposed between the first power line 120a and the second power line 120b. One or more signal lines 120c may be disposed between the first power line 120a and the second power line 120b and spaced apart from each other in the first direction D1.

The lower wiring structure BWS may include a gate contact 130c electrically connecting the second lower gate structure 110B2′ to the signal line 120c. The gate contact 130c may extend in the third direction D3. The gate contact 130c may transmit a signal from the signal line 120c to the second lower gate structure 110B2′. That is, the second lower gate structure 110B2′ may not be diffusion-insulated, and the second lower channel region 125B_C2 surrounded by the second lower gate structure 110B2′ may be a region through which current flows.

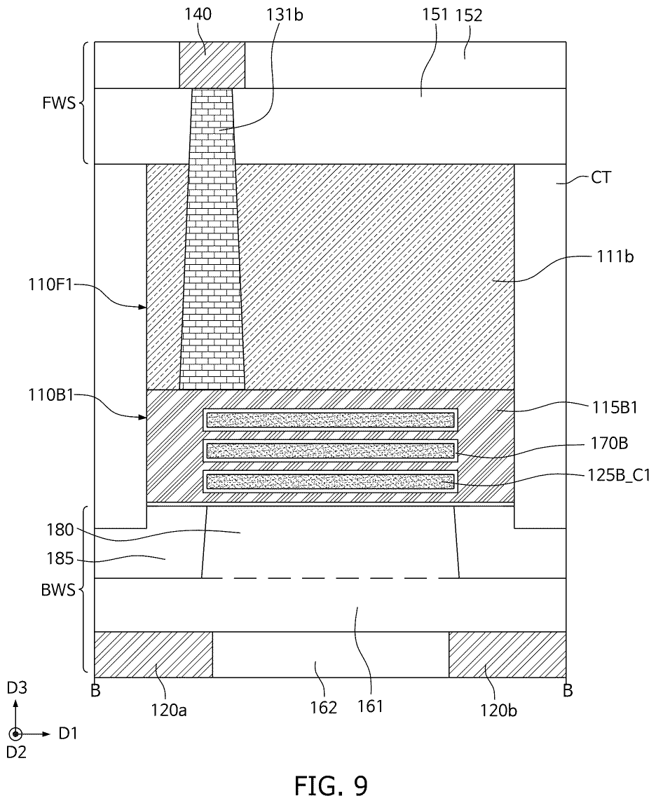

FIG. 9 is a diagram provided to explain some example embodiments of a semiconductor device.

The semiconductor device may include the first lower gate structure 110B1, the upper device isolation structure 110F1, the lower active region 125B, the upper wiring structure FWS, and the lower wiring structure BWS. Compared to the semiconductor device according to FIGS. 1 to 6, the semiconductor device according to FIG. 9 differs only in the characteristics related to the first contact plug 130b, and accordingly, descriptions overlapping those already described above will be omitted.

The semiconductor device according to FIG. 9 may include the first contact plug 130b disposed to extend through the upper device isolation structure 110F1. The first contact plug 130b may extend through the upper device isolation structure 110F1 in the third direction D3. The lower end of the first contact plug 130b may be in contact with an upper end of the first lower gate structure 110B1. The first contact plug 130b and the first lower gate structure 110B1 may be electrically connected to each other. Specifically, the first contact plug 130b may be electrically connected to the first lower gate electrode 115B1.

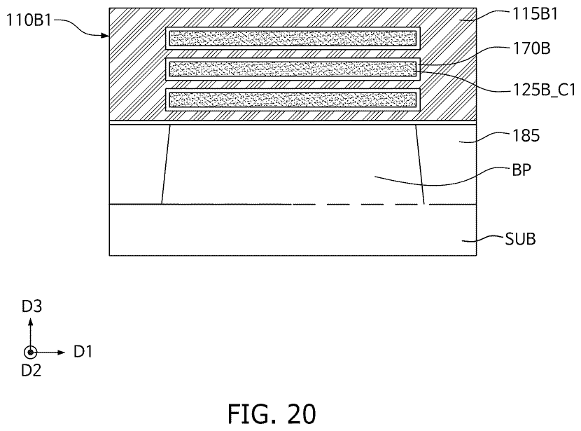

The cross-sectional width of the first contact plug 130b may increase from the upper end to the lower end. As described above, the shape of the first contact plug 130b of the semiconductor device according to FIG. 9 is different from the shape of the first contact plug 130 of the semiconductor device according to FIGS. 1 to 6 due to a difference in the manufacturing process, which will be described in detail below with reference to FIGS. 20 to 23.

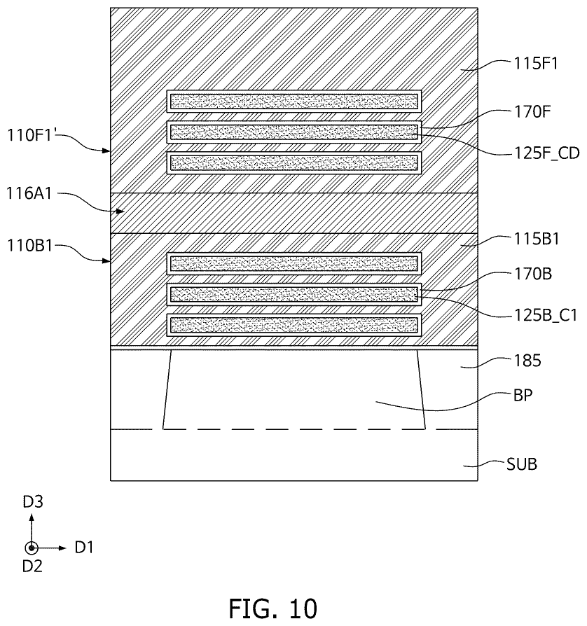

FIGS. 10 to 19 are diagrams provided to explain some example embodiments of methods for manufacturing a semiconductor device.

Some example embodiments of methods for manufacturing the semiconductor device will be described mainly with respect to a middle-of-line (MOL) process for forming a contact plug with reference to FIGS. 10 to 19.

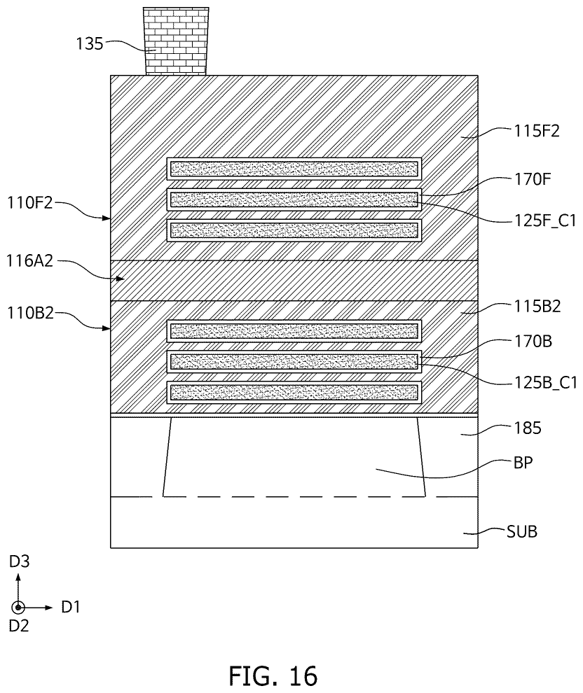

Referring to FIGS. 10 and 16, the first lower gate structure 110B1 and a dummy gate structure 110F1′ may be formed on a substrate SUB. The second lower gate structure 110B2 and the upper gate structure 110F2 may be formed on the substrate SUB at positions spaced apart from each of the first lower gate structure 110B1 and the dummy gate structure 110F1′ by a desired (and/or alternatively predetermined) distance in the second direction D2.

The substrate SUB may be a bulk silicon or a silicon-on-insulator (SOI). On the other hand, the substrate SUB may include silicon germanium (SiGe), silicon germanium on insulator (SGOI), indium antimony, lead tellurium compound, indium arsenic, indium phosphide, gallium arsenic, or gallium antimony, but example embodiments are not limited thereto.

A lower pattern BP may protrude from the substrate SUB. The lower pattern BP may extend in the first direction D1.

The first and second lower channel regions 125B_C1 and 125B_C2, the first upper channel region 125F_C1, and a dummy channel region 125F_CD may be disposed on the lower pattern BP. The first and second lower channel regions 125B_C1 and 125B_C2, the first upper channel region 125F_C1, and the dummy channel region 125F_CD may be spaced apart from the lower pattern BP in the third direction D3. The third direction D3 may be a direction perpendicular to an upper surface of the substrate SUB. The third direction D3 may be a thickness direction of the substrate SUB. The first and second lower channel regions 125B_C1 and 125B_C2, the first upper channel region 125F_C1, and the dummy channel region 125F_CD may have a nanosheet shape.

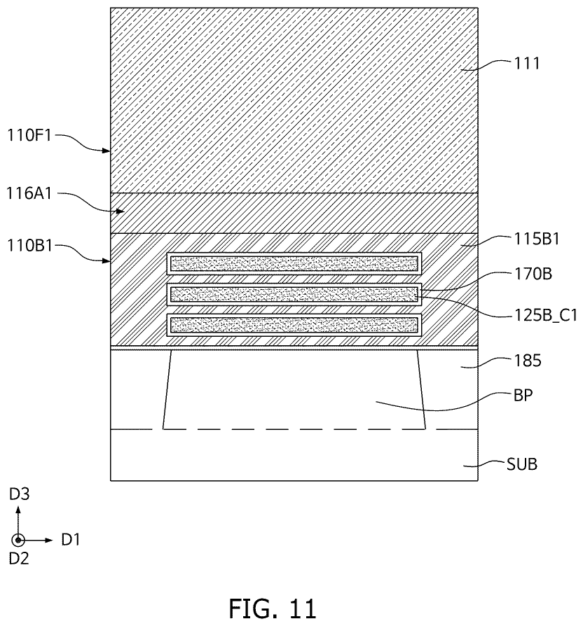

Referring to FIGS. 10 and 11, the dummy gate structure 110F1′ may be replaced with the upper device isolation structure 110F1. Specifically, the dummy gate structure 110F1′ may be removed. In this case, the dummy channel region 125F_C1 surrounded by the dummy gate structure 110F1′ may also be removed. Accordingly, the upper active region 125F may be divided into the first upper active region 125F1 and the second upper active region 125F2. The space formed after the dummy gate structure 110F1′ is removed may be filled with an insulating material 111. The insulating material 111 may include silicon oxide, silicon nitride, silicon oxynitride, silicon oxynitride, silicon oxynitride, or a combination thereof. For example, the insulating material 111 may be silicon nitride (Si₃N₄), but example embodiments are not limited thereto. Through this process, the dummy gate structure 110F1′ may be replaced with the upper device isolation structure 110F1. The first upper active region 125F1 and the second upper active region 125F2 may be physically separated and electrically insulated by the upper device isolation structure 110F1.

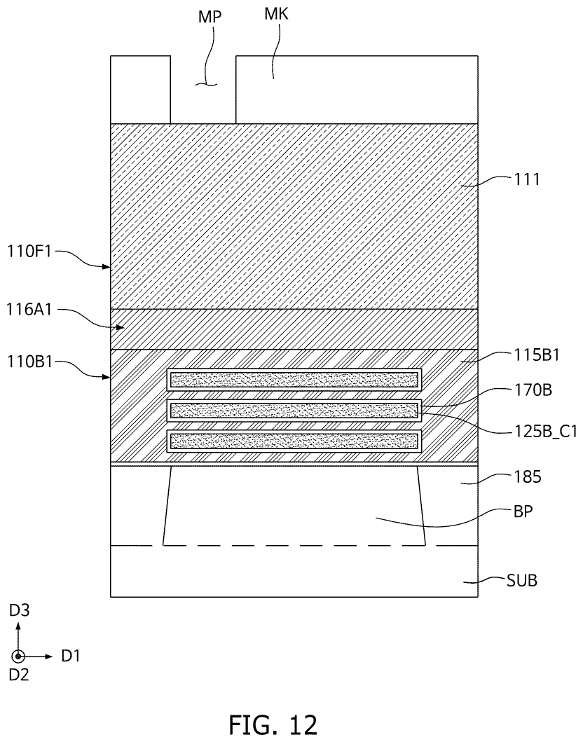

Referring to FIG. 12, a mask MK may be disposed on an upper surface of the upper device isolation structure 110F1. The mask MK may include a mask pattern MP.

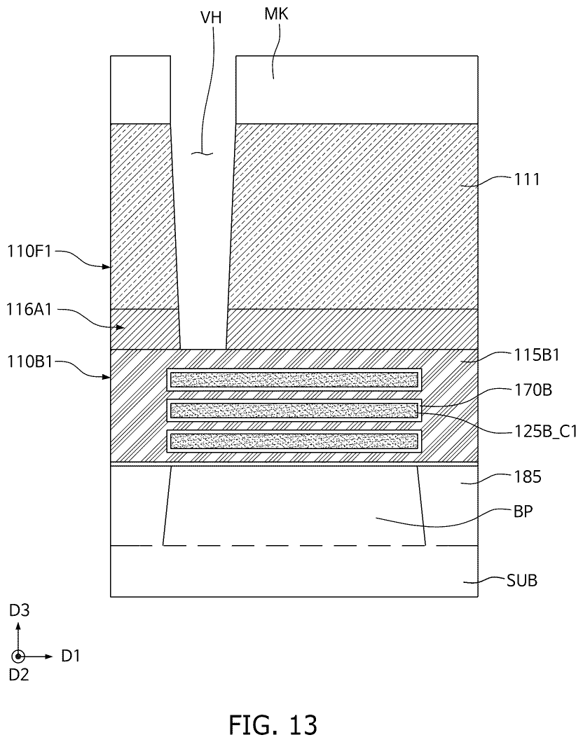

Referring to FIG. 13, a via hole VH may be formed by selectively etching the upper device isolation structure 110F1 formed of the insulating material 111, that is, by removing the insulating material 111. For example, a part of silicon nitride (Si₃N₄) included in the insulating material 111 may be removed through physical or chemical etching, resulting in only a part corresponding to the mask pattern MP being patterned. However, example embodiments are not limited thereto. Only the part exposed by the mask pattern MP may be patterned, while the part of the upper device isolation structure 110F1 covered by the mask MK remains.

The via hole VH may be formed in the upper device isolation structure 110F1 and the insulating layer 116A1 by etching. The via hole VH may be formed by the etching process such that the cross-sectional width thereof decreases according to depth. An end point EOP of the etching process may be an upper end of the first lower gate electrode 115B1. That is, the via hole VH may be formed up to the upper end of the first lower gate electrode 115B1.

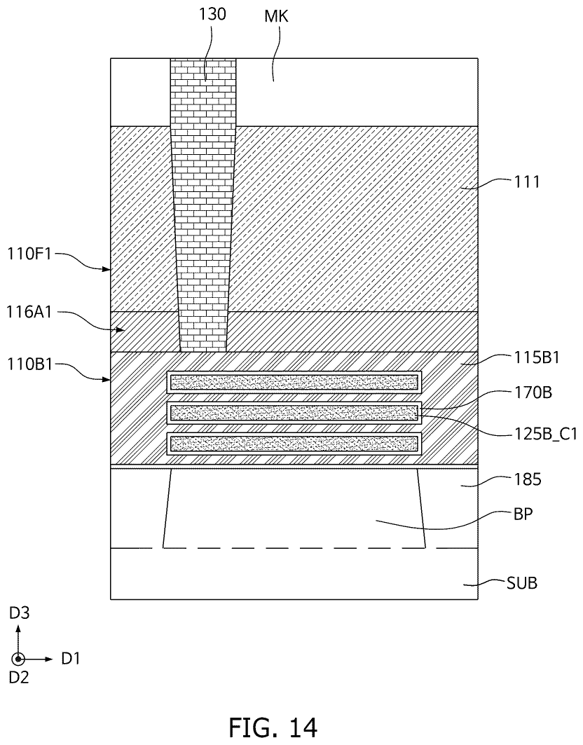

Referring to FIG. 14, the first contact plug 130 may be formed in the via hole VH. That is, a metal material for forming the first contact plug 130 may be filled in the via hole VH. For example, the first contact plug 130 may include at least one of tungsten (W), molybdenum (Mo), cobalt (Co), copper (Cu), aluminum (Al), titanium (Ti), tantalum (Ta), titanium/titanium (Ti/TiN), or a combination thereof. However, example embodiments are not limited thereto.

The first contact plug 130 may be electrically connected to the first lower gate electrode 115B1. Alternatively, the first contact plug 130 may be formed to be in contact with the first lower gate electrode 115B1. Although not illustrated, the first contact plug 130 may extend through the lower gate insulating film 170B surrounding the first lower gate electrode 115B1. The first contact plug 130 may be formed according to the shape of the via hole VH such that a cross-sectional width thereof decreases from the upper end to the lower end. However, the shape of the via hole VH and the first contact plug 130 is not limited thereto, and may be formed to have a substantially uniform cross-sectional width.

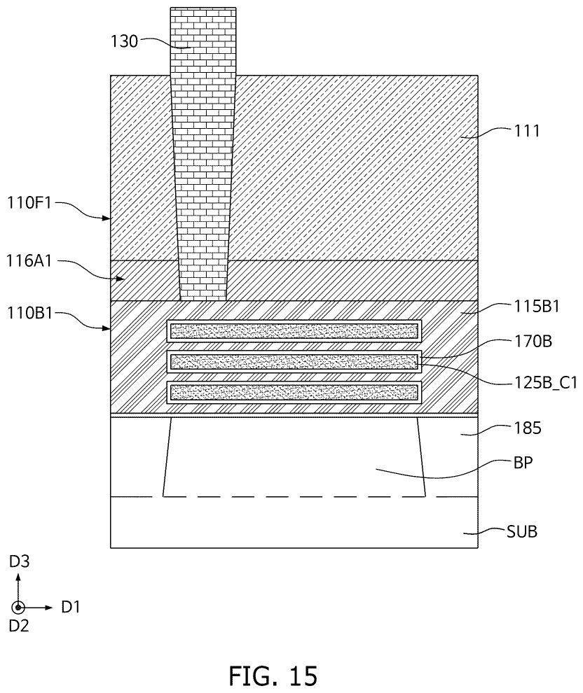

Referring to FIG. 15, the mask MK may be removed after the first contact plug 130 is formed. The thickness of the mask MK may be a protruding height of the first contact plug 130, that is, a distance from the upper end of the upper device isolation structure 110F1 to the connection wire 140.

Referring to FIG. 16, the second contact plug 135 may be formed on the upper side of the upper gate structure 110F2. The second contact plug 135 may include the same material as the first contact plug 130. The second contact plug 135 may be electrically connected to the upper gate electrode 115F2. The second contact plug 135 may be in contact with the second upper gate electrode 115F2. Although not illustrated, the second contact plug 135 may also extend through the upper gate insulating film 170F surrounding the second upper gate electrode 115F2.

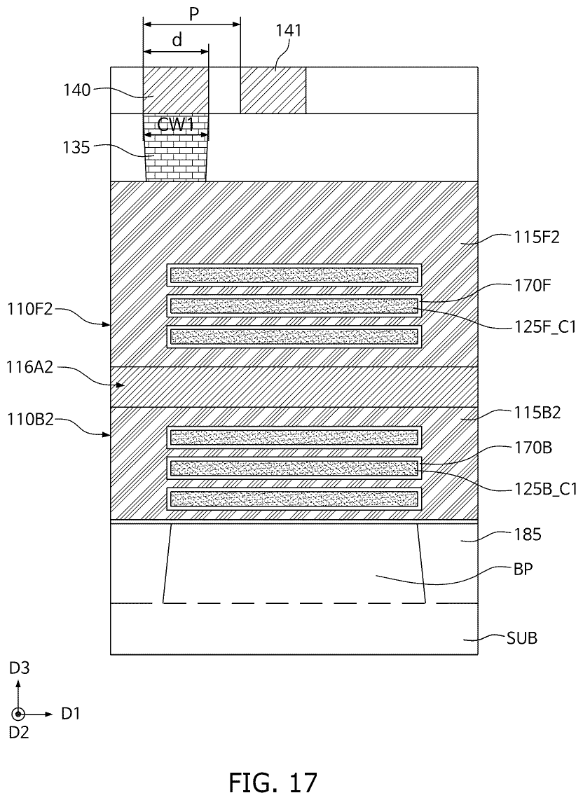

Referring to FIG. 17, the connection wire 140 may be disposed on the first contact plug 130 and the second contact plug 135. The upper end of the first contact plug 130 and the upper end of the second contact plug 135 may be in contact with the connection wire 140. Since the first contact plug 130 and the second contact plug 135 are disposed on the same line along the second direction D2, the first contact plug 130 may not be illustrated in FIG. 17.

The first contact plug 130 may have a width CW1 that is greater than or equal to a width d of the connection wire 140 based on the first direction D1. The width CW1 of the first contact plug 130 in the first direction D1 may be greater than or equal to the width d of the connection wire 140 in the first direction D1. It is illustrated in FIG. 17 that the width of the upper end of the first contact plug 130 in contact with the connection wire 140 in the first direction D1 is equal to the width d of the connection wire 140. However, example embodiments of describing the shape of the first contact plug 130 are not limited thereto. For example, the first contact plug 130 may be formed with the width greater than the width d of the connection wire 140.

A plurality of connection wires may be provided. A plurality of connection wires 140 and 141 may be disposed to be spaced apart from each other in the first direction D1. The plurality of connection wires 140 and 141 may include a first connection wire 140 connected to the first contact plug 130 and the second contact plug 135, and a second connection wire 141 disposed at a position spaced apart from the first connection wire 140 in the first direction D1. Although not illustrated, a contact plug for electrically connecting the second connection wire 141 and the gate structure may be formed.

The plurality of connection wires 140 and 141 may be spaced apart from each other by a desired (and/or alternatively predetermined) distance P. The first connection wire 140 and the second connection wire 141 may be spaced apart from each other by the desired (and/or alternatively predetermined) distance P in the first direction D1. The distance between the first connection wire 140 and the second connection wire 141 may be a distance between same portions of the first connection wire 140 and the second connection wire 141.

The width CW1 of the first contact plug 130 in the first direction D1 may be less than the distance P between the connection wires 140 and 141. For this reason, the first contact plug 130 may not be connected to another connection wire 141 adjacent to the connection wire 140 in contact with the upper end of the first contact plug 130.

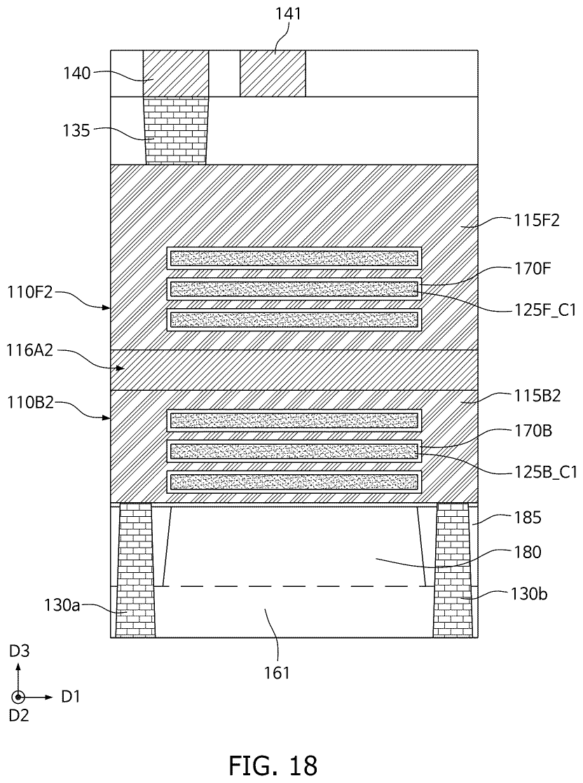

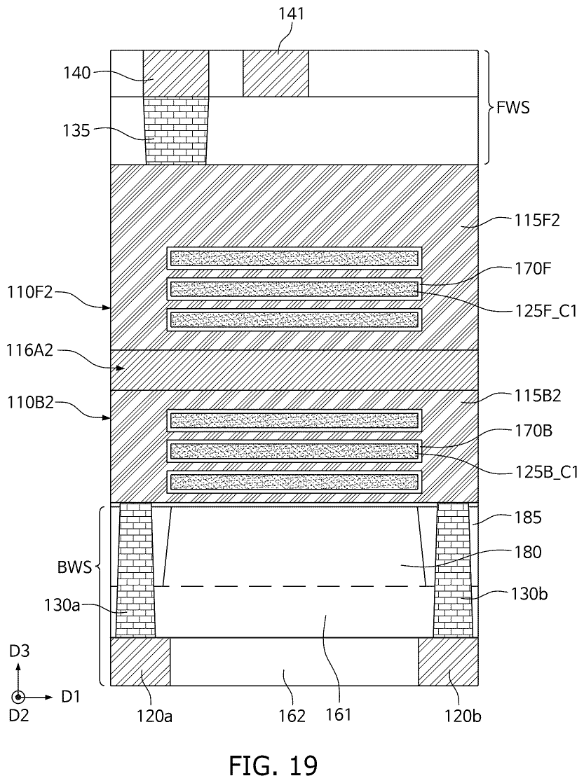

Referring to FIGS. 18 and 19, the lower wiring structure BWS may be formed under the semiconductor device. Specifically, the lower wiring structure BWS may be disposed under the second lower gate structure 110B2. However, for convenience of description, illustration of the inverted semiconductor device will be omitted.

The substrate SUB disposed on the lower side of the semiconductor device may be removed. The substrate SUB may be removed after inverting the semiconductor device such that the second lower gate structure 110B2 is positioned on the side. After the substrate SUB is removed, the lower pattern BP may be etched and the insulating material may be filled. That is, the interlayer insulating film 180 may be formed in the region from which the lower pattern BP has been removed.

The first lower wiring insulating film 161 may be formed under the interlayer insulating film 180 and the field insulating film 185. The first lower wiring insulating film 161 may be formed on the interlayer insulating film 180 and the field insulating film 185.

The lower wiring structure BWS may include the first lower gate contact 130a and a second gate contact 130B. The lower gate contacts 130a and 130b may be disposed under the second lower gate structure 110B2. The first lower wiring insulating film 161 and the field insulating film 185 (and/or the interlayer insulating film 180) may be etched to form the lower gate contacts 130a and 130b. A metal material for forming the lower gate contacts 130a and 130b may be filled in the region from which the first lower wiring insulating film 161 and the field insulating film 185 have been removed. That is, the first lower gate contact 130a and the second lower gate contact 130b may extend through the first lower wiring insulating film 161 and the field insulating film 185 (and/or the interlayer insulating film 180). The lower gate contacts 130a and 130b may be electrically connected to the second lower gate structure 110B2. That is, the lower gate contacts 130a and 130b may be in contact with the second lower gate electrode 115B2.

The second lower wiring insulating film 162 may be formed under the first lower wiring insulating film 161. The second lower wiring insulating film 162 may be disposed under the lower end of the first lower gate contact 130a and the lower end of the second lower gate contact 130b. That is, the second lower wiring insulating film 162 may be formed on the first lower wiring insulating film 161, the lower end of the first lower gate contact 130a, and the lower end of the second lower gate contact 130b.

The lower wiring structure BWS may include the first power line 120a and the second power line 120b. That is, it may be the Backside Power Delivery Network (BSPDN) method in which the wiring for supplying power to the semiconductor device is disposed under the semiconductor device. The first power line 120a and the second power line 120b may extend in the second direction. The first power line 120a and the second power line 120b may be spaced apart from each other in the first direction D1.

The second lower wiring insulating film 162 may be etched to form the first power line 120a and the second power line 120b. Specifically, the second lower wiring insulating film 162 may be etched such that the lower end of the first lower gate contact 130a and the lower end of the second lower gate contact 130b are exposed. The region from which the second lower wiring insulating film 162 has been removed may be filled with a metal material for forming the first power line 120a and the second power line 120b.

The first power line 120a and the second power line 120b may be positioned under the semiconductor device. The first power line 120a and the second power line 120b may be disposed to be spaced apart from each other in the first direction D1. The first lower gate contact 130a may be electrically connected to the first power line 120a, and the second lower gate contact 130b may be electrically connected to the second power line 120b. The upper end of the first lower gate contact 130a and the upper end of the second lower gate contact 130b may be electrically connected to the second lower gate electrode 115B2. The lower end of the first lower gate contact 130a and the lower end of the second lower gate contact 130b may be connected to the first power line 120a and the second power line 120b, respectively.

The second lower gate structure 110B2 may be electrically shorted or connected to the ground. That is, the second lower gate structure 110B2 may be a lower device isolation structure (electrical SDB). Specifically, current may not flow the second lower channel region 125B_C2 surrounded by the lower device isolation structure 110B2.

In another example, as described above with respect to FIGS. 7 and 8, the second lower gate structure 110B2′ may not be a device isolation structure, and the second lower gate structure 110B2′ may be connected to one or more signal lines 120c.

FIGS. 20 to 23 are diagrams provided to explain some example embodiments of methods for manufacturing a semiconductor device.

Referring to FIGS. 20 to 23, some example embodiments of methods for manufacturing the semiconductor device may form the first lower gate structure 110B1 and the upper device isolation structure 110F1.

Referring to FIG. 20 first, the first lower gate structure 110B1 may be formed. Since this is the same process as described above with reference to FIGS. 10 and 11, description of the method of removing the dummy gate structure disposed on the first lower gate structure 110B1 will be omitted.

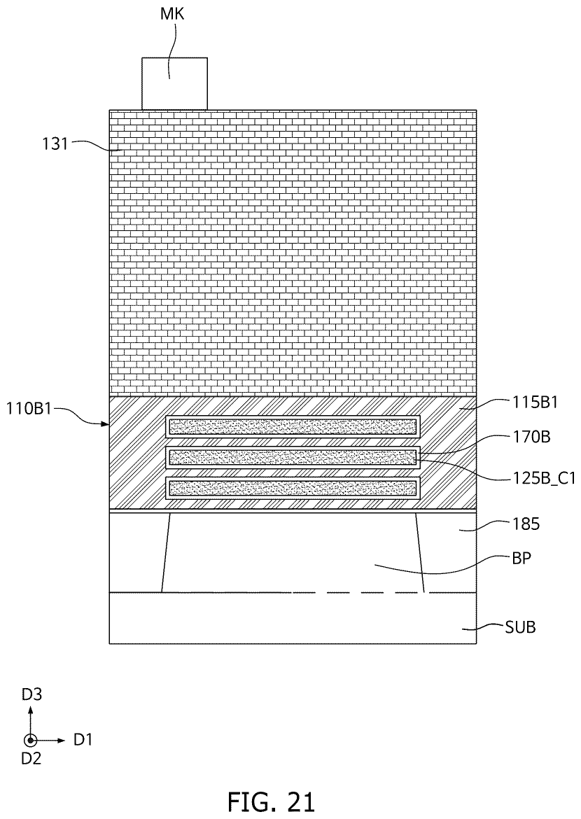

Referring to FIG. 21, a metal structure 131 may be formed on the first lower gate structure 110B1. For example, the metal structure 131 may include at least one of tungsten (W), molybdenum (Mo), cobalt (Co), copper (Cu), aluminum (Al), titanium (Ti), tantalum (Ta), titanium/titanium (Ti/TiN), or a combination thereof. However, example embodiments are not limited thereto.

Like the first lower gate structure 110B1, the metal structure 131 may extend in the first direction D1. The mask MK may be disposed above the metal structure 131. The mask MK may be disposed at a position where the first contact plug 130 is to be formed.

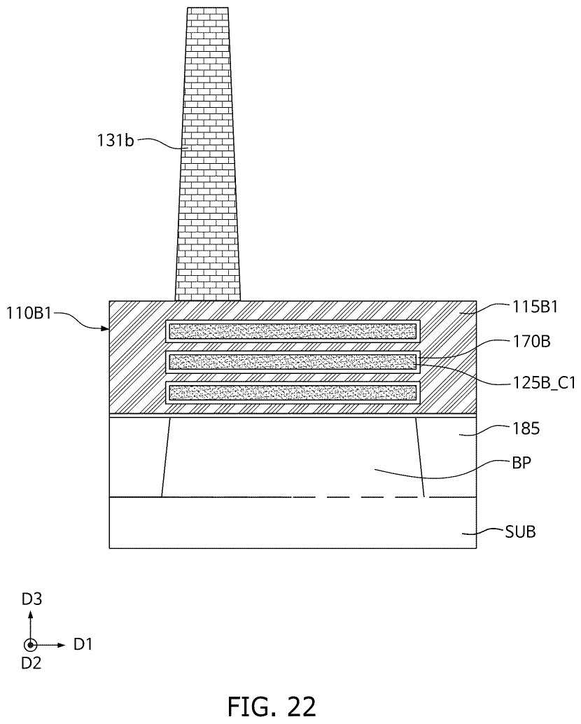

Referring to FIG. 22, the metal structure 131 may recess a portion of the metal structure 131 through an etching process. That is, a portion except for the portion where the mask MK is positioned, that is, the portion other than the first contact plug 131b may be removed. Through this etching, the first contact plug 131b may be formed such that the cross-sectional width thereof increases from the upper end to the lower end.

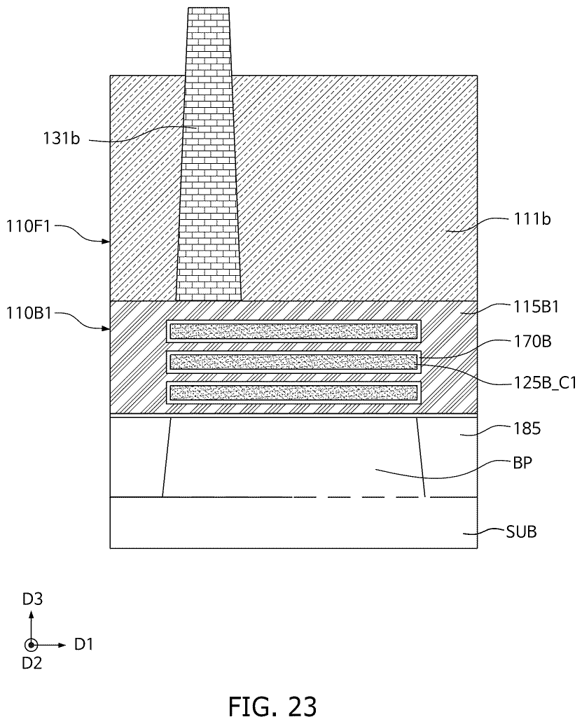

Referring to FIG. 23, after the first contact plug 131b is formed, an insulating material 111b may be formed on the first lower gate structure 110B1. The insulating material 111b may be filled in a portion of the upper device isolation structure 110F1 except for the portion occupied by the first contact plug 131b.

The upper device isolation structure 110F1 may separate adjacent transistors by the insulating material 111b. Since the process of connecting the upper wiring structure FWS and the lower wiring structure BWS is the same as the process of the manufacturing method of FIGS. 10 to 19, descriptions overlapping those already described above will be omitted.

Some example embodiments of the present disclosure have been described above for purposes of illustration only, and those skilled in the art with ordinary knowledge of the present disclosure will be able to make various modifications, changes and additions within the spirit and scope of the present disclosure, and such modifications, changes and additions should be construed to be included in a scope of the claims.

1. A semiconductor device, comprising:
a first lower gate structure extending in a first direction;
an upper device isolation structure extending from the first lower gate structure in the first direction;
a second lower gate structure spaced apart from the first lower gate structure in a second direction, the second direction intersecting the first direction, and the second lower gate structure extending in the first direction;
an upper gate structure extending from the second lower gate structure in the first direction;
a lower active region extending in the second direction and extending through the first lower gate structure;
an upper active region extending in the second direction and extending through the upper gate structure; and
a first contact plug extending through the upper device isolation structure in a third direction, the third direction intersecting the first direction and the second direction, and the first contact plug contacting the first lower gate structure.

2. The semiconductor device according to claim 1, further comprising:
a second contact plug on the upper gate structure in the third direction; and
a connection wire electrically connected to an upper end of each of the first contact plug and the second contact plug.

3. The semiconductor device according to claim 2, wherein
the connection wire extends in the second direction, and
the first contact plug and the second contact plug are spaced apart from each other in the second direction.

4. The semiconductor device according to claim 2, wherein
the lower active region includes a first lower channel region surrounded by the first lower gate structure, and
the first contact plug overlaps the first lower channel region in the third direction.

5. The semiconductor device according to claim 4, wherein at least a portion of the first contact plug overlaps an upper source and drain region of the upper active region in the second direction.

6. The semiconductor device according to claim 5, wherein a contact insulating film is between the first contact plug and the upper source and drain region.

7. The semiconductor device according to claim 1, wherein
the upper device isolation structure includes an insulating material, and
the upper active region contacting at least one side surface of the upper device isolation structure.

8. The semiconductor device according to claim 1, wherein
the lower active region includes a second lower channel region surrounded by the second lower gate structure, and
the second lower gate structure is a lower device isolation structure that is electrically shorted.

9. The semiconductor device according to claim 8, wherein
a first lower gate contact is electrically connected to a first power line,
a second lower gate contact is electrically connected to a second power line, and
the first lower gate contact and the second lower gate contact are under the second lower gate structure.

10. The semiconductor device according to claim 9, wherein the first power line and the second power line are connected to a same power source.

11. The semiconductor device according to claim 1, wherein
the second lower gate structure is a lower device isolation structure including an insulating material, and
the lower active region is contacting at least one side surface of the second lower gate structure.

12. The semiconductor device according to claim 1, wherein
the lower active region includes a second lower channel region surrounded by the second lower gate structure, and
the second lower gate structure is electrically connected to a signal line through a gate contact.

13. The semiconductor device according to claim 1, wherein the first contact plug has a cross-sectional width that increases in the third direction from an upper portion to a lower portion.

14. A semiconductor device, comprising:
a first lower gate structure extending in a first direction;
an upper device isolation structure extending from the first lower gate structure in the first direction;
a lower device isolation structure spaced apart from the first lower gate structure in a second direction, the second direction intersecting the first direction, and lower device isolation structure extending in the first direction;
an upper gate structure extending in the first direction on the lower device isolation structure;
a lower active region extending in the second direction to intersect the first lower gate structure, and the lower active region including a lower channel region surrounded by the first lower gate structure;
an upper active region extending in the second direction to intersect the upper gate structure, and the upper active region including an upper channel region surrounded by the upper gate structure; and
a first contact plug extending through the upper device isolation structure in a third direction, the third direction intersecting the first direction and the second direction, and the first contact plug contacting the first lower gate structure;
a second contact plug extending in the third direction and contacting the upper gate structure; and
a connection wire connected to an upper end of each of the first contact plug and the second contact plug.

15. The semiconductor device according to claim 14, wherein
the connection wire extends in the second direction, and
the first contact plug and the second contact plug are spaced apart from each other in the second direction.

16. The semiconductor device according to claim 15, wherein
the connection wire is a first connection wire, and
the semiconductor device further includes a second connection wire spaced apart from the first connection wire in the first direction, and
a width of the first contact plug in the first direction is greater than a width of the first connection wire and smaller than a distance between the first connection wire and the second connection wire.

17. The semiconductor device according to claim 14, wherein
the upper device isolation structure includes an insulating material, and
the upper active region contacting at least one side surface of the upper device isolation structure.

18. The semiconductor device according to claim 14, wherein the lower device isolation structure is electrically shorted.

19. The semiconductor device according to claim 14, wherein a width of the first contact plug in the second direction is less than or equal to a thickness of the upper device isolation structure.

20. A semiconductor device, comprising:
a first lower gate structure extending in a first direction;
an upper device isolation structure extending from the first lower gate structure in the first direction and including an insulating material;
a lower device isolation structure extending in the first direction and spaced apart from the first lower gate structure in a second direction, the second direction being orthogonal to the first direction, and the lower device isolation structure being electrically shorted;
an upper gate structure extending from the lower device isolation structure in the first direction;
a lower active region extending in the second direction to intersect the first lower gate structure, and the lower active region including a lower channel region surrounded by the first lower gate structure;
a lower source and drain region on a side surface of the first lower gate structure;
an upper active region extending in the second direction to intersect the upper gate structure, and the upper active region including an upper channel region surrounded by the upper gate structure;
an upper source and drain region on a side surface of the upper device isolation structure;
a first contact plug extending through the upper device isolation structure in a third direction, the third direction intersecting the first direction and the second direction, and the first contact plug in contact at a lower end with the first lower gate structure;
a second contact plug on the upper gate structure in the third direction and contacting a lower end of the upper gate structure; and
a connection wire extending in the second direction and contacting an upper end of the first contact plug and an upper end of the second contact plug.
